(19) United States
(12) Patent Application Publication
(10) Pub. No.: US 2026/0040691 A1
(43) Pub. Date: Feb. 5, 2026

(54) THERMAL SHUTOFF FOR ELECTROSTATIC DISCHARGE CLAMPS AND METHODS OF MANUFACTURING THE SAME

(71) Applicant: TEXAS INSTRUMENTS INCORPORATED, Dallas, TX (US)

(72) Inventors: Xuehao Mou, Plano, TX (US); Rajkumar Sankaralingam, Plano, TX (US)

(21) Appl. No.: 18/790,504

(22) Filed: Jul. 31, 2024

(51) Int. Cl. H01L 27/02; H02H 9/04

(52) U.S. Cl. CPC H10D 89/711; H02H 9/046; H10D 89/911; H10D 89/921

(57) ABSTRACT

A device is disclosed herein. The device includes a first power rail, a second power rail, an electrical protection component conductively coupled between the first and second power rails, the electrical protection component configured to monitor a voltage characteristic of the power rail to thereby detect an electrical event, and a thermal protection component conductively coupled between the power rails, and to the electrical protection component, the thermal protection component including a temperature-sensitive transistor configured to alter an electrical characteristic of the electrical protection component in response to a change in temperature of the device.

### FIELD

The present disclosure generally relates to semiconductor devices and more particularly to electrostatic overstress circuits in semiconductor devices.

### BACKGROUND

Integrated circuits (ICs) may be severely damaged by electrostatic overstress (EOS) events, including electrostatic discharge (ESD) events. Sources of EOS events include electric discharge from human bodies, from metallic objects, power on events, among others. During an EOS event there may be a spike in voltage and/or current in the IC. The spike in current and/or voltage may have a shorter than expected rise time that tends to place a higher-than-normal stress on the IC. The rapid charge, or discharge, of voltage and/or current from the IC tends to stress the IC. This stress tends to degrade and/or damage the components of the IC. ESD circuits are coupled to the IC to mitigate the stresses and damage caused by a spike in voltage and/or current in the IC.

### SUMMARY

Disclosed herein is a device including a first power rail, a second power rail, an electrical protection component conductively coupled between the first and second power rails, the electrical protection component configured to monitor a voltage characteristic of the power rail to thereby detect an electrical event, and a thermal protection component conductively coupled between the power rails, and to the electrical protection component, the thermal protection component including a temperature-sensitive transistor configured to alter an electrical characteristic of the electrical protection component in response to a change in temperature of the device.

Also disclosed herein is a device including a power rail, a reference rail, an ESD protection component conductively coupled to the power rail and the reference rail, and a thermal protection component. The thermal protection component includes a first transistor including a first gate terminal conductively coupled to the reference rail and a bipolar junction transistor (BJT). The BJT includes a base conductively coupled to the first transistor, a collector configured to provide a control signal to a control terminal of the ESD protection component, and an emitter conductively coupled to the reference rail, wherein the BJT is configured to alter the control signal in response to a change of temperature of the device.

Also disclosed herein is a method of manufacturing an integrated circuit including forming an ESD protection circuit on or over a substrate, the ESD protection circuit configured to operate responsive to a transient electrical event on a power rail and forming a thermal protection circuit on or over the substrate, the thermal protection circuit being connected to a control terminal of the ESD protection circuit, wherein the thermal protection circuit includes a temperature sensitive component configured to modulate a control voltage at the control terminal in response to a change of temperature of the integrated circuit.

The foregoing features and elements may be combined in any combination, without exclusivity, unless expressly indicated herein otherwise. These features and elements as well as the operation of the disclosed examples will become more apparent in light of the following description and accompanying drawings.

### BRIEF DESCRIPTION OF THE DRAWINGS

Reference will now be made to the accompanying drawings, which are not necessarily drawn to scale. While the drawings illustrate various examples employing the principles described herein, the drawings do not limit the scope of the claims.

FIG. 1 illustrates functional diagram of a circuit, in accordance with various examples.

FIG. 2 illustrates a schematic diagram of a circuit in accordance with the functional diagram of FIG. 1 and the various examples associated therewith.

FIG. 3 illustrates a schematic diagram of a circuit in accordance with the functional diagram of FIG. 1 and the various examples associated therewith.

FIGS. 4A and 4B illustrate graphs of circuit and voltage characteristics in accordance with the functioning of the schematic diagram of FIG. 2 and the various examples associated therewith.

FIGS. 5A and 5B illustrate graphs of circuit and voltage characteristics in accordance with the functioning of the schematic diagram of FIG. 3 and the various examples associated therewith.

FIG. 6 illustrates a flowchart for a method of forming an integrated circuit in accordance with the schematic diagrams of FIGS. 2 and 3 and the various examples associated therewith.

FIG. 7 illustrates a timing diagram of various components of the schematic diagram of FIG. 2 and the various examples associated therewith.

FIG. 8 illustrates a timing diagram of various components of the schematic diagram of FIG. 3 and the various examples associated therewith.

### DETAILED DESCRIPTION

The following detailed description is presented for purposes of illustration and not of limitation. Benefits, advantages, and/or solutions to problems may be described with reference to various examples. The detailed description makes use of the various examples and refers to the accompanying drawings which illustrate the various examples described herein. The drawings, descriptions, and examples are described in sufficient detail to practice the disclosure. It is understood that connecting lines shown in the various drawings are intended to represent exemplary functional relationships and/or physical couplings between various elements, but that other relationships and/or couplings are possible while remaining within the scope of the present disclosure. It will further be appreciated that the various drawings may not be drawn to scale in order to simplify and clarify the detailed description herein. Furthermore, it is understood that the descriptions and examples contained herein may permit the practice other examples using logical, chemical, and/or mechanical changes without departing from the spirit and scope of this disclosure. For example, the steps recited in method and process descriptions may be executed in a different order, additional process steps may be added, and/or process steps may be removed while remaining within the scope of the present disclosure.

Any reference to singular items and/or examples includes plural items and/or examples and any reference to more than one item and/or example may include a singular item and/or example. Similarly, references to “a”, “an”, or “the” may include one or more of the referenced items, unless stated otherwise. Any reference to connected, coupled, fixed, attached, or the similar words and/or phrases may include partial, full, temporary, removable, permanent, or the other connection options. Any reference to contact, or similar phrase, may include minimal contact or reduced contact. All ranges used herein may include both the upper and lower values of the ranges, including ratio limits, that are disclosed herein. Stated values may include at least the variation that is expected within the field in which the present disclosure is practiced and as would be understood and accepted to include values that are within 10% of a stated value. Similarly, the use of “approximately”, “about”, “substantially” or other similar term represents an amount that is close to the stated value and that may still achieve the stated, or desired, result and/or perform the stated, or desired, function and may refer to an amount that is within 10% of the stated value.

The accompanying drawings, and detailed description of the drawings, include reference numerals that may be repeated across multiple examples. The repetition of reference numerals is intended simplicity and clarity of description and is not intended to form or dictate a relationship between different examples described herein. The examples and descriptions provided herein are intended to be exemplary and not limiting beyond the scope of the claims. The use of terms such as “on” and “over” may indicate that a first feature is formed directly contacting a second feature or may indicate a relationship of the first feature and the second feature without direct contact between the two, such as additional features being formed between the two.

Spatially relative terms such as, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of discussion herein and are not intended to limit the orientation of the various components, systems, apparatuses, devices, or other features. It is therefore understood and appreciated that the use of the spatially relative terms to practice this disclosure in different orientations remains within the scope of the present disclosure.

Rate-triggered ESD clamps, or circuits, may turn-on inadvertently during fast supply rail ramp up (e.g., an ESD event) leading to EOS failures. Some such ESD clamps include high voltage transistors, e.g. drain-extended (DE) nMOS (DENMOS) transistors. The EOS immunity of the ESD clamp may be improved by designing the high voltage transistor to have a high safe operating area (SOA) margin over the operating voltage. That is, the high voltage transistors may be oversized for the intended purpose of the application to provide the high SOA margin. However, some high voltage transistors have a SOA that degrades at high temperatures (e.g., above about 150° C).

Disclosed herein are systems and methods for protecting ESD clamps from failure voltage when operating at high temperatures. In various examples, the described systems and methods provide a circuit-based solution for protecting the ESD clamps. In various examples, a thermal shutoff component is included as part of the ESD clamp. In various examples, the thermal shutoff modifies an electrical characteristic (e.g., a gate voltage) of the ESD clamp in response to an increase in temperature of the ESD clamp. In various examples, the thermal shutoff component improves the failure voltage of the ESD clamp by decreasing the high voltage transistor’s gate drive in response to operating at the high temperature.

In various examples, the thermal shutoff component may be used to reduce leakage current through the ESD clamp that may result from operating at a high temperature (e.g., about 175° C to about 225° C). In various examples, by including the thermal shutoff component the high-power transistor may be smaller than otherwise possible. That is, the high-power transistor can have a smaller SOA, and therefore be physically smaller, when the thermal shutoff component is present.

In various examples, the thermal shutoff component includes a pull-down circuit that is conductively coupled to a gate terminal of the high voltage transistor. In various examples, pull-down circuit includes a bipolar transistor, such as an NPN bipolar junction transistor (BJT). In various examples, the pull-down circuit is configured to weakly pull down the gate voltage of the high voltage transistor at room temperature (“RT”, e.g., about 27° C) but turn-on more strongly at high temperatures (e.g., about 175° C to about 225° C). In various examples, such operation tends to decrease the effective gate bias on the high voltage transistor at high temperatures, thus increasing the failure voltage of the high-power transistor.

Reference will be made throughout the present disclosure to various concepts such as voltage, temperature, time frames, and physical size, among others. It is understood that these design parameters, operating ranges and ranges of use associated with each of the mentioned concepts are intended to be exemplary and not limiting. In various examples, reference may be made to normal, room temperature, and high temperatures, among others. These references are intended for purposes of description as temperature ranges that constitute high or normal may be specific to a design choice or intended application. The descriptions and examples included in the present disclosure may be adapted for the specific integrated circuit that is being designed while remaining within the scope of the present disclosure.

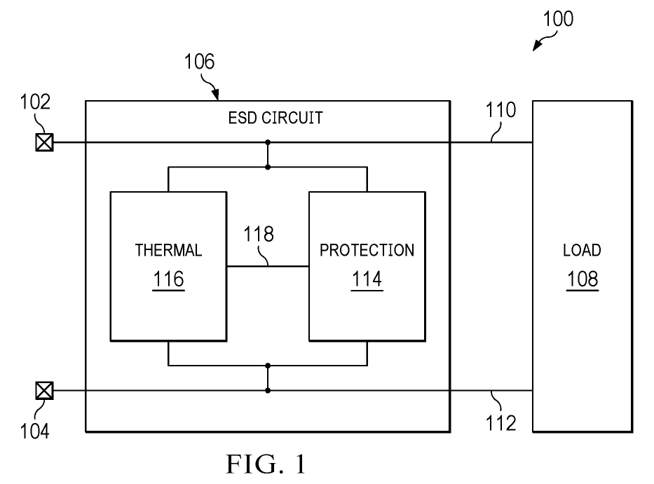

Referring now to FIG. 1, a functional diagram of a circuit 100 is illustrated, in accordance with various examples of the present disclosure. Circuit 100 includes a first pad 102, a second pad 104, an ESD protection circuit 106, a load 108, a first power rail 110, and a second power rail 112. In various examples, first power rail 110 may be configured to provide a positive voltage, a negative voltage, or ground. In various examples, second power rail 112 may be configured to provide a positive voltage, a negative voltage, or ground. For ease of discussion and simplicity, first power rail 110 will be referred to as having a higher voltage, sometimes referred to as V_{dd}, and the second power rail 112 will be referred to as having a lower voltage, sometimes referred to as Vₛₛ. In various examples, load 108 may be a circuit, or other component, that is powered by the potential difference between first power rail 110 and second power rail 112. ESD protection circuit 106 provides ESD or EOS protection for load 108. As illustrated, ESD protection circuit 106 is conductively coupled to first power rail 110, second power rail 112, and load 108.

ESD protection circuit 106 further includes a protection circuit 114 and a thermal protection circuit 116. Protection circuit 114 and analogous protection circuits are sometimes referred to as actFET cells herein without limitation. Additional aspects of actFET cells are described in US Patent No. 8,804,290, incorporated herein by reference in its entirety.

Both actFET cell 114 and thermal protection circuit 116 are conductively coupled to first power rail 110 and second power rail 112. ActFET cell 114 is configured to protect load 108 from EOS events, including ESD events. Thermal protection circuit 116 is configured to protect actFET cell 114, and more broadly ESD protection circuit 106, from the adverse effects of an increase in temperature of ESD protection circuit 106. Thermal protection circuit 116 is conductively coupled to actFET cell 114 by a control line 118. Thermal protection circuit 116 may, in various examples, send a signal to actFET cell 114 that is responsive to the temperature of ESD protection circuit 106, including thermal protection circuit 116 and actFET cell 114, exceeding a predetermined threshold temperature.

During operation, power may be initially applied (“power-on”) to circuit 100 by first pad 102 and second pad 104 (e.g., first pad 102 at V_{dd} and second pad 104 at ground). In such operation the voltage and/or current is expected to increase at a known rate. Under normal conditions, ESD protection circuit 106 does not affect the voltage and/or current between first power rail 110 and second power rail 112 and subsequently load 108 may operate as expected.

During fast transient events, such as ESD events, abnormal power on events, and/or power supply noise, among others, the voltage and/or current on first power rail 110 may increase at a rate much higher than normal, or spike, for a short period of time. During such a fast transient event, ESD protection circuit 106 may be activated and is configured to shunt current from first power rail 110 to second power rail 112 to quickly reduce the magnitude of the voltage spike, thus minimizing the wear and/or damage to load 108. However, when operating at elevated temperatures, as may occur in industrial or automotive settings, the SOA of a high voltage transistor in the actFET cell 114 may be reduced. Thus, the increased temperature may cause wear and/or damage to components of ESD protection circuit 106 including actFET cell 114. Thermal protection circuit 116 may be configured to react to this rise in temperature and adjust the operation of the actFET cell 114 via control line 118 to actFET cell 114 to reduce and/or minimize the effect of the increased temperature and avoid damage to ESD protection circuit 106 including actFET cell 114. Specifically, thermal protection circuit 116 is configured to reduce the turn-on sensitivity of actFET cell 114 at high temperatures, thereby partly disabling ESD protection circuit 106 at high temperatures. For simplicity, the function of ESD protection circuit 106 may be described below with respect to ESD events, though it is understood that other fast transient events are within the scope of the present disclosure.

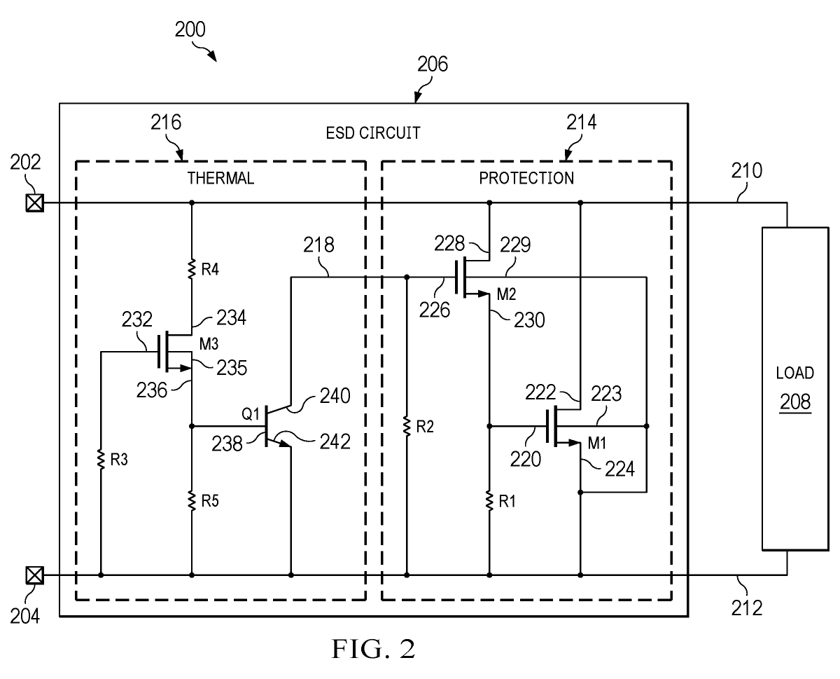

Referring now to FIG. 2, a schematic diagram of a circuit 200 is illustrated, in accordance with various examples of the present disclosure. Circuit 200 includes some analogous components to circuit 100 described above in FIG. 1, including a first pad 202, a second pad 204, an ESD protection circuit 206, a load 208, a first power rail 210, a second power rail 212, an actFET cell 214, a thermal protection circuit 216, and a control line 218, descriptions of which may not be repeated below. Circuit 200, in various examples, may be especially effective for mitigating problems associated with rapid change in voltage EOS events at elevated operating temperature. Additional details of actFET cell 214 and thermal protection circuit 216 and their operation will be described below, in accordance with various examples. It should be appreciated that the configuration of actFET cell 214 and thermal protection circuit 216 may vary from what is illustrated and described below while remaining within the scope of the present disclosure.

ActFET cell 214 includes a first transistor M1, a second transistor M2, a first resistor R1, and a second resistor R2 which are interconnected as shown. First transistor M1 includes a first gate terminal 220, a first drain terminal 222, a first body terminal 223, and a first source terminal 224. In various examples, first transistor M1 may be a metal oxide semiconductor field effect transistor (MOSFET), a power MOSFET, an insulated-gate bipolar transistor (IGBT), a laterally diffused MOSFET (LDMOS), complimentary MOSFET (CMOS), drain extended MOSFET (DEMOS), or another transistor. That is, first transistor M1 may be designed to handle large currents, such as those associated with ESD events. In various examples, first transistor M1 may be a high voltage transistor. In various examples, first transistor M1 may have an SOA that decreases as temperature increases due to intrinsic physical effects of temperature on the constituent materials of the transistor. Generally, the physical size of first transistor M1 is related to the SOA, such that a transistor with a lower SOA may be made larger to provide a desired predetermined failure voltage, while transistors having a higher SOA may be made smaller for the same failure voltage. Therefore, in various examples, the SOA and physical size may be selected for the intended use. The SOA of a semiconductor device (e.g., first transistor M1) defines the voltage and current conditions over which the semiconductor device can operate without damage. In some high voltage transistors (e.g., IGBT), the SOA tends to degrade significantly at temperatures that are higher than RT (e.g. higher than about 27° C).

In various examples, second transistor M2 includes a second gate terminal 226, a second drain terminal 228, a second body terminal 229, and a second source terminal 230. In various examples, second transistor M2 may be a field effect transistor (FET), a MOSFET, or another transistor. In various examples, second transistor M2 may be designed to handle a lower current than first transistor M1. In various examples, second transistor M2 may be a high voltage transistor that has a lower maximum voltage than first transistor M1. Furthermore, second transistor M2 forms a source follower circuit with first transistor M1. This allows first transistor M1 to be biased at a higher voltage and for a longer period of time than would otherwise be possible. Because of this, and in various examples, second transistor M2 may be physically smaller than first transistor M1.

Thermal protection circuit 216 includes a third transistor M3, a bipolar junction transistor (BJT) Q1, a third resistor R3, a fourth resistor R4, and a fifth resistor R5 which are interconnected as illustrated. Third transistor M3 includes a third gate terminal 232, a third drain terminal 234, a third body terminal 235, and a third source terminal 236. In various examples, second transistor M2 and third transistor M3 may be nominally identical instances of a same component, such as a FET, a MOSFET, or another transistor. In various examples, third transistor M3 may be the same size as second transistor M2 or a different size (e.g. smaller or larger). The relative smaller size of third transistor M3 as compared to transistor M1 helps reduce the area of thermal protection circuit 216. BJT Q1 includes a base 238, a collector 240, and an emitter 242. As illustrated in FIG. 2, first transistor M1, second transistor M2, and third transistor M3 are n-type MOSFET (NMOS) transistors. In various examples, first transistor M1, second transistor M2, and/or third transistor M3 may be a p-type MOSFET (PMOS) transistor, depending on the intended application.

As illustrated in FIG. 2, and with respect to actFET cell 214, second gate terminal 226 is conductively coupled to second resistor R2 and to collector 240, via control line 218. Second drain terminal 228 is conductively coupled to first power rail 210. Second body terminal 229 is conductively coupled to first body terminal 223, first source terminal 224, and second power rail 212. Second source terminal 230 is conductively coupled to first gate terminal 220 and first resistor R1. First gate terminal 220 is conductively coupled to second source terminal 230 and first resistor R1. First drain terminal 222 is conductively coupled to first power rail 210. First body terminal 223 is conductively coupled to second body terminal 229, first source terminal 224, and second power rail 212. First source terminal 224 is conductively coupled to first body terminal 223 and second power rail 212. A first end of first resistor R1 is conductively coupled to first gate terminal 220 and second source terminal 230 and a second end of first resistor R1 is conductively coupled to first power rail 210. A first end of second resistor R2 is conductively coupled to second gate terminal 226 and collector 240 and a second end of second resistor R2 is conductively coupled to first power rail 210. While this is one implementation of actFET cell 214, it is understood that other rate-triggered circuit implementations are contemplated and are within the scope of the present disclosure. In various other examples, first body terminal 223 and/or second body terminal 229 may be conductively coupled to first power rail 210, second power rail 212, and/or other power rails and/or ground rails, among other electrical components.

As illustrated in FIG. 2, and with respect to thermal protection circuit 216, third gate terminal 232 is conductively coupled to third resistor R3. Third drain terminal 234 is conductively coupled to fourth resistor R4. Third body terminal 235 is conductively coupled to third source terminal 236, base 238, and fifth resistor R5. Third source terminal 236 is conductively coupled to base third body terminal 235, base 238, and fifth resistor R5. Base 238 is conductively coupled to third body terminal 235, third source terminal 236, and fifth resistor R5. Collector 240 is conductively coupled to second gate terminal 226 and second resistor R2, via control line 218. Emitter 242 is conductively coupled to second power rail 212. A first end of third resistor R3 is conductively coupled to third gate terminal 232 and a second end of third resistor R3 is conductively coupled to second power rail 212. A first end of fourth resistor R4 is conductively coupled to third drain terminal 234 and a second end of fourth resistor R4 is conductively coupled to first power rail 210. A first end of fifth resistor R5 is conductively coupled to third body terminal 235, third source terminal 236, and base 238 and a second end of fifth resistor R5 is conductively coupled to second power rail 212. While this is one implementation of thermal protection circuit 216, it is understood that other configurations are possible while remaining with the scope of the present disclosure. In various other examples, third body terminal 235 may be conductively coupled to first power rail 210 second power rail 212, and/or other power rails and/or ground rails, among other electrical components. In various other examples, base 238 of Q1 may be conductively coupled to other components and/or be part of a different circuit layout while remaining within the scope of this disclosure.

Continuing with FIG. 2, as previously mentioned, actFET cell 214 provides ESD protection functionality of ESD protection circuit 206 and thermal protection circuit 216 provides the thermal protection functionality of ESD protection circuit 206. As previously stated, in various examples, second transistor M2 affects the bias voltage of first transistor M1. As will be described in greater detail below, during an ESD event second transistor M2 turns on first, causing a voltage drop across first resistor R1, turning on first transistor M1.

There is a capacitance C_{gd1} between second gate terminal 226 and second drain terminal 228. Resistor R2 and C_{gd1} act as a high-pass filter of V_{dd} at the second gate terminal 226. During an ESD event, the voltage at second gate terminal 226 of first transistor M1 is pumped up by second resistor R2 and capacitance C_{gd1}. As the voltage is pumped up, second transistor M2 provides a current through first resistor R1 to turn on first transistor M1. Once turned on, first transistor M1 provides a path to shunt the current associated with the ESD event from first power rail 210 to second power rail 212. That is, during a sharp rise in voltage on first power rail 210 caused by an ESD event, capacitance C_{gd1} is charged resulting in a voltage at second gate terminal 226 that exceeds a threshold voltage for second transistor M2 causing second transistor M2 to turn on. Current flows from first power rail 210 to second power rail 212 through second transistor M2, and more specifically, from second drain terminal 228 to second source terminal 230, in response to second transistor M2 turning on. During such an ESD event, a voltage at first gate terminal 220 is generated by first resistor R1 causing first transistor M1 to turn on when the voltage at first gate terminal 220 exceeds a threshold voltage for first transistor M1. Once first transistor M1 is turned on, actFET cell 214 then shunts the current from first power rail 210 to second power rail 212 through first transistor M1, and more specifically, from first drain terminal 222 to first source terminal 224. As described earlier, the ESD protection circuit will have an operating environment with an ambient temperature that depends on the implementation. An operating temperature of ESD protection circuit 206 will reflect the ambient temperature and may also be affected by power dissipation during an ESD event as the first transistor M1 shunts current between the first power rail 210 and the second power rail 212. This power dissipation may increase the operating temperature of the actFET cell 214, and in particular the first transistor M1.

To prevent damage from occurring to ESD protection circuit 206 due to a decrease of failure voltage of first transistor M1 caused by an increase in temperature, thermal protection circuit 216 provides a thermal shutoff capability to ESD protection circuit 206. That is, as the operating temperature of the IC increases, thermal protection circuit 216 provides, via control line 218, a signal to actFET cell 214 to decrease the operating voltage of actFET cell 214 by reducing the voltage at second gate terminal 226, which tends to protect actFET cell 214, and more specifically first transistor M1, from early failure.

Operation of thermal protection circuit 216 is similar to operation of actFET cell 214. During normal operation (e.g. the IC is performing within design limits), thermal protection circuit 216 is not active. During an ESD event, thermal protection circuit 216 is activated in a similar manner as described above for actFET cell 214. That is, third transistor M3 has a gate drain capacitance C_{gd2} between third drain terminal 234 and third gate terminal 232 that charges in response to the ESD event. Third transistor M3 is charged by the voltage on first power rail 210, analogous to second transistor M2, providing a current through fifth resistor R5 to turn on BJT Q1. At normal operating temperatures (e.g., room temperature), BJT Q1 diverts a small amount of current or charge from second resistor R2. The current diverted by BJT Q1 may be sufficiently small that second transistor M2 continues to operate as described above. As the operating temperature increases, the gain current gain, or β, increases. Therefore, as the temperature of the IC rises (including that of thermal protection circuit 216) BJT Q1 has a higher pull-down strength and diverts more current from second resistor R2, effectively reducing the resistance between the second gate terminal 226 and the second power rail 212 (e.g. ground). This lower resistance in turn lowers the maximum gate voltage at second gate terminal 226. By lowering the maximum gate voltage at second gate terminal 226, the current through first resistor R1 is also decreased thereby reducing the peak gate voltage at first gate terminal 220 during the voltage transient event. Accordingly, reducing the maximum gate voltage at first gate terminal 220 during an ESD event is expected to reduce or prevent damage from occurring to the actFET cell 214.

In various examples, fourth resistor R4 of the thermal protection circuit 216 limits the gate voltage of third transistor M3 (e.g., third gate terminal 232) across different ramp rates of ESD events and prevents an overdrive of BJT Q1 and/or insensitivity to temperature. That is, fourth resistor R4 tends to reduce the sensitivity of third transistor M3 to the voltage and/or current ramp rate of thermal protection circuit 216 to maintain the sensitivity of third transistor M3 to the temperature increase.

In various examples, actFET cell 214 and thermal protection circuit 216 may be a single integrated circuit. In some other examples, actFET cell 214 and thermal protection circuit 216 may be separate integrated circuits. In yet other examples, the separate circuits may be thermally coupled such that the operation of the thermal protection circuit 216 reflects the thermal environment of the actFET cell 214.

As described above, thermal protection circuit 216 enables the operation of actFET cell 214 over larger temperature ranges than would otherwise be the case. As the operating temperature of ESD protection circuit 206 increases, the shunt current provided by the BJT Q1 is regarded as a control signal provided by control line 218 that alters or modulates the operating characteristics of actFET cell 214. Specifically, in various examples, the altered operating characteristics may include lower peak gate voltage at first gate terminal 220, lower peak gate voltage at second gate terminal 226, and/or reduced peak current flow through the second resistor R2. Accordingly, as the operating temperature of ESD protection circuit 206 rises, thermal protection circuit 216 draws a higher current from actFET cell 214, lowering the gate voltages of first transistor M1 and second transistor M2 to decrease the sensitivity of first transistor M1 to higher temperatures.

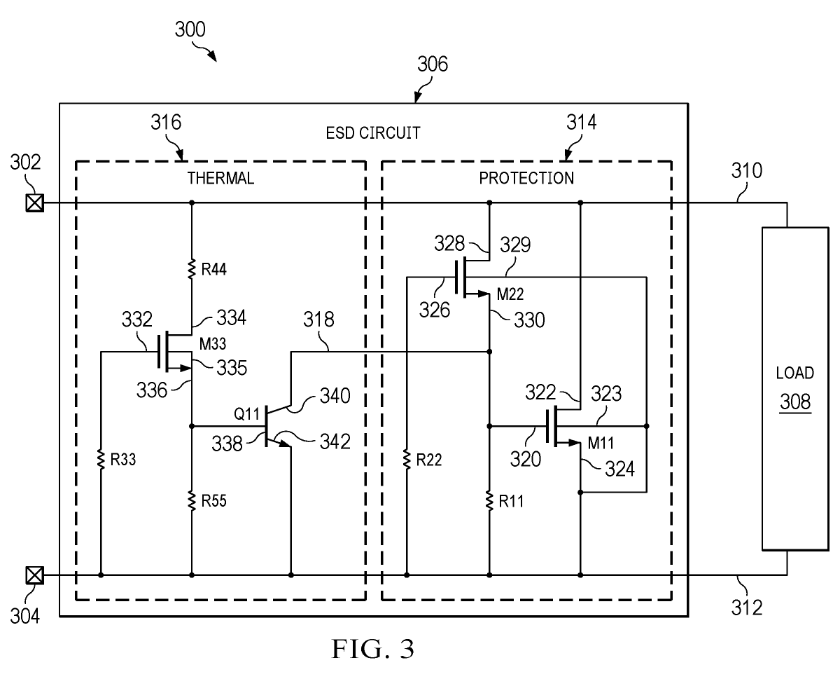

Referring now to FIG. 3, a schematic diagram of a circuit 300 is illustrated, in accordance with various alternate examples of the present disclosure. Circuit 300 includes analogous components to circuit 200 described above in FIG. 2, including a first pad 302, a second pad 304, an ESD protection circuit 306, a load 308, a first power rail 310, a second power rail 312, an actFET cell 314, a thermal protection circuit 316, and a control line 318, descriptions of which may not be repeated below. ActFET cell 314 includes analogous components to actFET cell 214 described above in FIG. 2, including a first transistor M11, a second transistor M22, a first resistor R11, a second resistor R22, a first gate terminal 320, a first drain terminal 322, a first body terminal 323, a first source terminal 324, a second gate terminal 326, a second drain terminal 328, a second body terminal 329, and a second source terminal 330, descriptions of which may not be repeated below. While this is one implementation of actFET cell 214, it is understood that other rate-triggered circuit implementations are contemplated and are within the scope of the present disclosure. In various other examples, first body terminal 323 and/or second body terminal 329 may be conductively coupled to first power rail 310, second power rail 312, and/or other power rails and/or ground rails, among other electrical components. Thermal protection circuit 316 includes similar components to thermal protection circuit 216 described above in FIG. 2, including a third transistor M33, a BJT Q11, a third resistor R33, a fourth resistor R44, a fifth resistor R55, a third gate terminal 332, a third drain terminal 334, a third body terminal 335, a third source terminal 336, a base 338, a collector 340, and a emitter 342, descriptions which may not be repeated below. While this is one implementation of thermal protection circuit 216, it is understood that other configurations are possible while remaining with the scope of the present disclosure. In various other examples, third body terminal 335 may be conductively coupled to first power rail 310, second power rail 312, and/or other power rails and/or ground rails, among other electric components.

In various examples, circuit 300 differs from circuit 200 in that collector 340 is conductively coupled to first gate terminal 320, second source terminal 330, and first resistor R11 via control line 318. By this connection of control line 318, ESD protection circuit 306 may have a lower leakage current than the ESD protection circuit 206.

During normal, or quiescent, operation (e.g. an ESD event is not occurring), leakage current of low power transistors such as the second transistor M22 tends to be greater at higher temperatures. Leakage current through second transistor M22 in response to a temperature increase of the IC may result in a greater voltage at first gate terminal 320, thus causing first transistor M11 to partially turn on. Turning on the first transistor M11 in this manner would allow current to flow from first power rail 310 to second power rail 312 through first transistor M11. This current path can drain energy from a source of V_{dd}, such as a battery, coupled to the first pad 302 and second pad 304, thereby potentially reducing operating life of a device of which the circuit 300 is a part and/or can heat up circuit 300, among other effects.

Thermal protection circuit 316 reduces the leakage current through actFET cell 314 that would otherwise occur at elevated operating temperature. In that regard, control line 318, and more specifically collector 340 being conductively coupled to first gate terminal 320, lowers the gate bias of first transistor M11, thereby reducing the drain-to-source conductivity of the first transistor M11. As the temperature of circuit 300 increases (whether during an ESD event or even during normal operations), leakage current through first transistor M11, second transistor M22, and third transistor M33 may increase. The increase in leakage current through second transistor M22 generates a positive voltage across first resistor R11 at first gate terminal 320 of first transistor M11. As the voltage at first gate terminal 320 increases, first transistor M11 turns on allowing more current to leak through first transistor M11. Similarly, the increase in leakage current through third transistor M33 generates a positive voltage across fifth resistor R55 at base 338 of BJT Q11. As the voltage at base 338 increases at the higher temperature, BJT Q11 allows a greater current to flow between the collector 340 and the emitter 342, thus shunting a portion of the leakage current from the second transistor M22 to ground (via control line 318) and lowering the voltage at first gate terminal 320. The lowered voltage at first gate terminal 320 reduces and/or eliminates the leakage current through first transistor M11.

Accordingly, thermal protection circuit 316 enables the reduction or prevention of leakage current through actFET cell 314 at elevated operating temperature. The sink current via the control line 318 is regarded as a control signal provided by thermal protection circuit 316 that alters or modulates the operating characteristics of actFET cell 314. Specifically, in various examples, control line 318, and more specifically collector 340 being conductively coupled to first gate terminal 320, allows thermal protection circuit 316 to lower the gate bias of first transistor M11 to reduce leakage current through actFET cell 314 as the temperature increases.

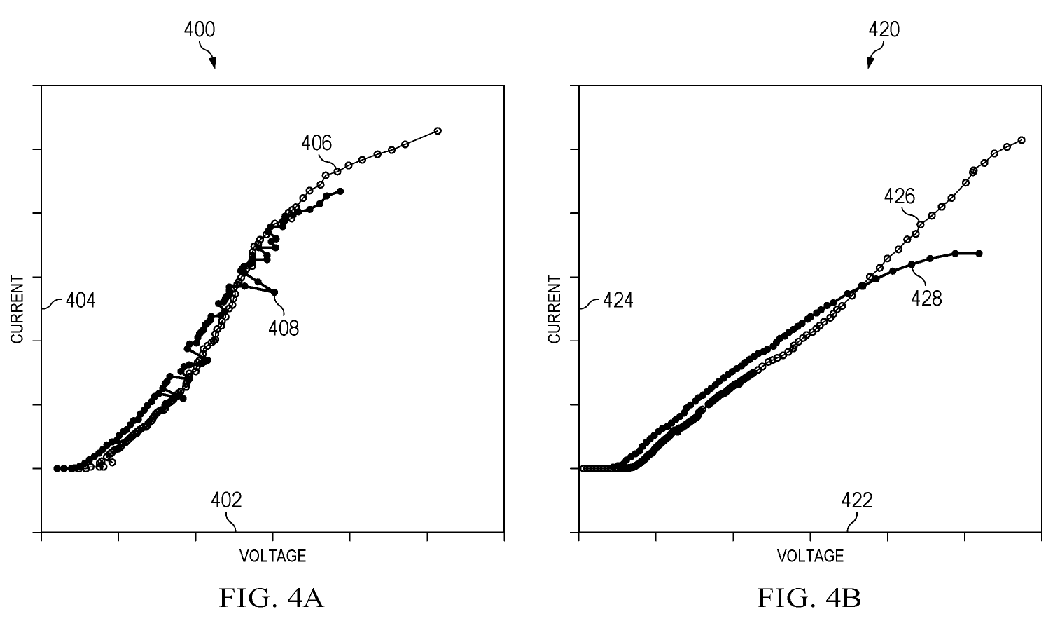

Referring now to FIGS. 4A and 4B, graphs illustrate characteristics the operating voltage (V_{dd}-Vₛₛ) and current (V-I) at two different temperatures of manufactured ESD protection circuits in which the high voltage transistor is implemented as an IGBT. FIG. 4A shows a first graph 400 illustrating the V-I characteristic of a baseline ESD protection circuit, such as exemplified by the actFET cell 214 without the thermal protection circuit 216. First graph 400 has a voltage axis 402 (e.g., the x-axis), a current axis 404 (e.g., the y-axis), a first line 406, and a second line 408. The first line 406 and the second line 408 end at different maximum temperatures that represent different failure voltages of the corresponding transistors. First line 406 includes a plurality of points illustrating a V-I characteristic of the baseline ESD protection circuit operating at about RT (e.g. about 27° C). Second line 408 includes a plurality of points illustrating a V-I characteristic of the baseline ESD protection circuit operating at a temperature consistent with operation in an industrial or automotive environment (e.g. about 200° C, referred to without limitation as “hot”). The first line 406 (RT) shows a first failure voltage, and the second line 408 (hot) shows a second lower failure voltage. The difference between the first and second failure voltages represents a baseline example of the reduction of failure voltage for an actFET such as the actFET cell 214 without protection by a thermal protection circuit.

FIG. 4B shows a second graph 420 that illustrates the V-I characteristics of a thermally protected ESD protection circuit as exemplified by the ESD protection circuit 206 including both the actFET cell 214 and the thermal the thermal protection circuit 216. Second graph 420 has a voltage axis 422 (e.g., the x-axis), a current axis 424 (e.g., the y-axis), a first line 426, and a second line 428. The voltage axes 402 and 422 have a same scale. First line 426 includes a plurality of points representing a V-I characteristic of the thermally protected ESD protection circuit operating at RT, while second line 428 includes a plurality of points representing a V-I characteristic of the thermally protected ESD protection circuit operating at about 200° C. As before, first line 426 and second line 428 end at different maximum temperatures that represent different failure voltages of the corresponding thermally protected ESD protection circuits. The first line 426 shows a first failure voltage similar (somewhat greater) to that of the first line 406 (unprotected actFET cell at RT). However, the second line 428 shows a second lower failure voltage that is relatively close to the failure voltage of first line 426 and significantly greater than the failure voltage of second line 408 (hot unprotected actFET). The greater failure voltage of the second line 428 represents a significant improvement of the expected reliability of an ESD protection circuit including a thermal protection circuit exemplified by the thermal protection circuit 216.

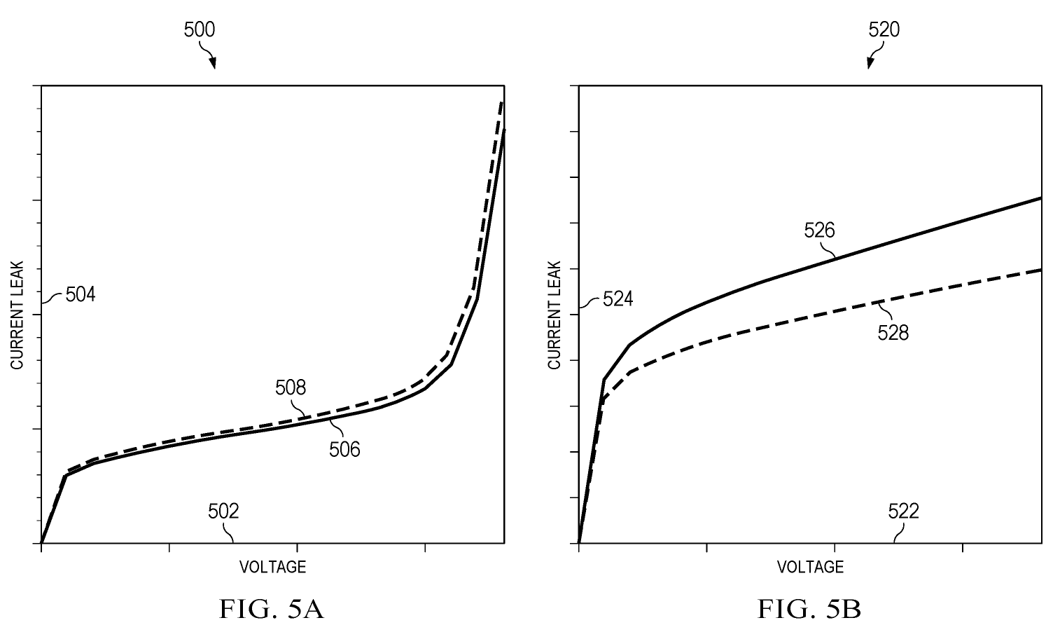

Referring now to FIGS. 5A and 5B, graphs showing V-I characteristics of simulated leakage current as a function of operating voltage for circuits including an actFET such as exemplified by actFET cell 314. FIG. 5A shows a first graph 500 having a voltage axis 502 (e.g., the x-axis), a leakage current axis 504 (e.g., the y-axis), a first line 506, and a second line 508. First graph 500 illustrates the leakage current as a function of operating voltage of the actFET when operating at RT. First line 506 illustrates a V-I characteristic of the actFET in an ESD protection circuit without the thermal shutoff circuit. Second line 508 illustrates a V-I characteristic of an ESD protection circuit including an actFET and a thermal protection circuit as exemplified by thermal protection circuit 316 and interconnected with the actFET via a control line such as exemplified by control line 318 in ESD protection circuit 306. As shown by the lines 506 and 508, the leakage current of the ESD protection circuit including the thermal protection circuit increases only slightly with increasing operating voltage at RT.

FIG. 5B is a second graph 520 having a voltage axis 522 (e.g., the x-axis), a leakage current axis 524 (e.g., the y-axis), a first line 526, and a second line 528. The voltage axis 522 has the same scaling as the voltage axis 502 and the leakage current axis 524 has the same scaling as the leakage current axis 504. Second graph 520 illustrates the leakage current characteristics of the ESD protection circuits without (first line 526) and with (second line 528) the thermal protection circuit operating at 200° C. The leakage current of both circuits is greater than those shown in the first graph 500 except near the top of the illustrate voltage range. But the second line 528 shows a leakage current of the ESD protection circuit with the thermal protection circuit as much as 20% less than that of the unprotected actFET illustrated by the first line 526. Thus, in implementations for which leakage current is a concern, e.g. low-power or battery-powered devices, the thermal protection circuit may provide a significant increase of operational lifetime.

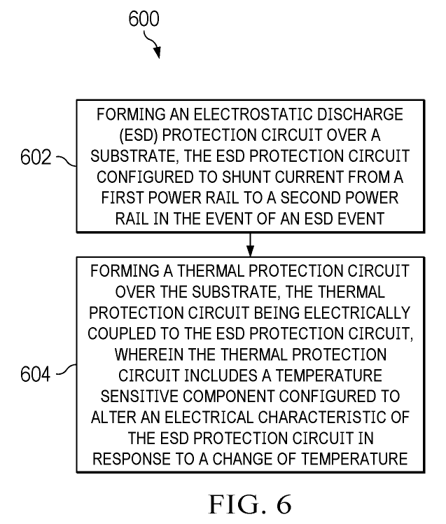

Referring now to FIG. 6, a flow diagram of a method 600 for forming an ESD circuit, including a protection circuit and a thermal shutoff circuit is illustrated, in accordance with various examples of the present disclosure. In various examples, method 600 may be used to form ESD protection circuit 206 and/or ESD protection circuit 306. At step 602, an ESD protection circuit is formed over a semiconductor substrate. The ESD protection circuit is configured to shunt current from a first power rail to a second power rail in the event of an ESD event. At step 604, a thermal protection circuit is formed over the substrate. The thermal protection circuit is electrically coupled to the ESD protection circuit, and the thermal protection circuit includes a temperature sensitive component that is configured to alter an electrical characteristic of the ESD protection circuit in response to a change of temperature.

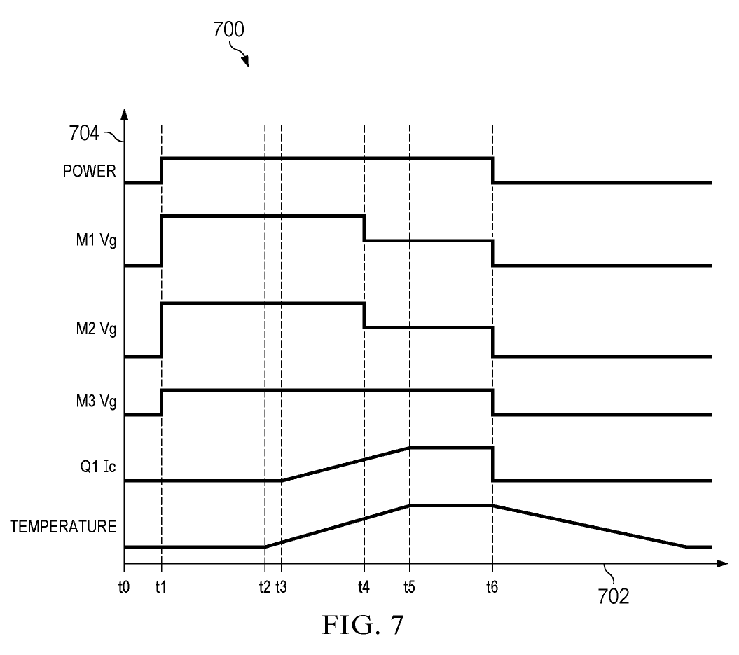

Referring now to FIG. 7, a timing diagram 700 for an ESD protection circuit is illustrated, in accordance with various examples of the present disclosure. Timing diagram 700 is an illustration of the operation of ESD protection circuit 206 described above with respect to FIG. 2 and is used for illustrative and description purposes only. That is, timing diagram 700 is simplified for clarity purposes. As such, it is understood that timing diagram 700 may not fully illustrate the subject electrical signals as they may occur in an actual device. Instead, timing diagram 700 illustrates the relative timing of the different events occurring in ESD protection circuit 206 in response to an ESD event.

Timing diagram 700 has a time axis 702 (e.g., the x-axis) and y-axis 704 that qualitatively reflects the magnitude of the subject device parameter, such as voltage, current, or temperature. At time t0 the ESD protection circuit has an initial operating temperature that is relatively constant and reflects the operating conditions of the device of which the ESD protection circuit is a part. For example, in automotive or industrial implementations the initial operating temperature that may be 200° C or more.

At time t1, the power voltage (e.g., first power rail 210) increases to a first voltage as part of a transient event, such as an ESD event. The gate voltage of second transistor M2 and the gate voltage of third transistor M3 are both charged by the power voltage transient, turning on second transistor M2 and third transistor M3, as described previously. Current from second transistor M2 generates a gate voltage at first transistor M1, turning on first transistor M1 to shunt current between the power rails of the ESD protection circuit. Additionally, current from third transistor M3 energizes a control terminal, e.g. a base, of BJT Q1, turning on BJT Q1.

At time t2, the temperature of the circuit may begin to increase. Any increase above the initial operating temperature will depend on the length and magnitude of the ESD event, and therefore the power dissipated by the transistor M1. At time t3, BJT Q1 draws more current in response to the increased temperature. At time t4, the increased current draw by BJT Q1 causes a voltage drop at second transistor M2 which causes a voltage drop at first transistor M1, as previously discussed. The voltage drop at first transistor M1 protects first transistor M1 from damage caused by high voltage at higher temperatures (e.g., greater than about 175° C), e.g. by ensuring the first transistor M1 remains within its SOA. At time t4, the temperature reaches a steady state and the current draw by BJT Q1 remains steady. At time t6, the transient event ends with the power supply voltage returning the original state. First transistor M1, second transistor M2, third transistor M3, and BJT Q1 each turn off in response to the power voltage drop.

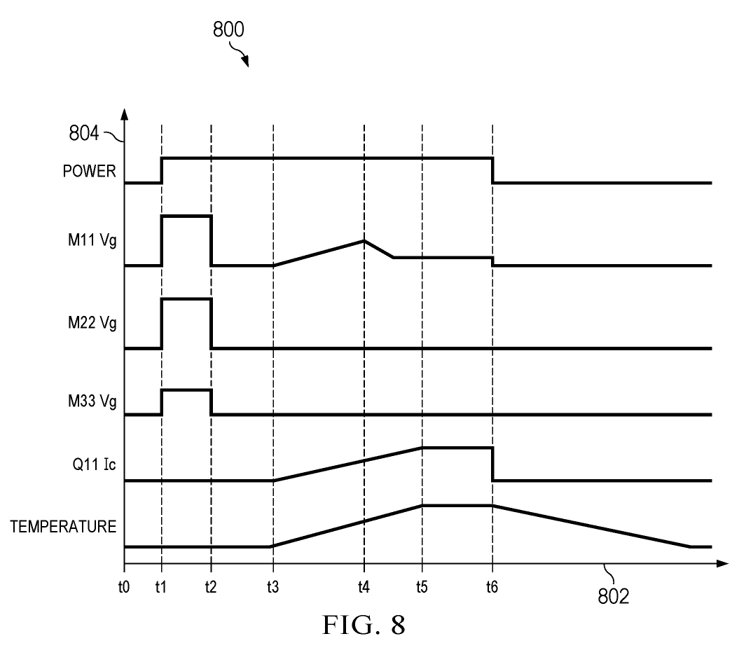

Referring now to FIG. 8, a timing diagram 800 for an ESD circuit is illustrated, in accordance with various examples of the present disclosure. Timing diagram 800 is an illustration of the operation of ESD protection circuit 306 described above with respect to FIG. 3 and is used for illustrative and description purposes only, similar to timing diagram 700 described above in FIG. 7. Timing diagram 800 illustrates similar concepts as timing diagram 700 including the voltage, current, and temperature of the ESD circuit (e.g., ESD protection circuit 106 and ESD protection circuit 306) as a function of time. Timing diagram 800 includes similar components as timing diagram 700, including a time axis 802 (e.g., the x-axis) and y-axis 804, the value of y-axis 804 may be different depending on the what the component is. At time t0 the ESD protection circuit has an initial operating temperature that is relatively constant and reflects the operating conditions of the device of which the ESD protection circuit is a part.

At time t1, the power voltage (e.g., first power rail 310) increases to a first voltage as part of a transient event, such as a power on event. First transistor M11, second transistor M22, and third transistor M33 behave similar to described above in response to the transient event. At time t2, first transistor M11, second transistor M22, and third transistor M33 each turn off in response to the steady power on state. At time t3, the temperature of the circuit begins to increase. The increased temperature causes a voltage increase at the gate of first transistor M11 due to current leak through second transistor M22. Additionally, the current flow through BJT Q11 increases in response to the increased temperature, as described above. At time t4, the gate voltage of first transistor M11 begins to decrease in response to the increased current flow through BJT Q11. At time t5, the temperature reaches a steady state, the current draw by BJT Q1 remains steady, and the gate voltage of first transistor M11 remains steady, minimizing current leak through first transistor M11. At time t6, the power voltage returns to the original state (e.g., powered off). First transistor M11 turns off, BJT Q11 turns off, and the temperature begins to decrease.

Accordingly, the circuits and methods disclosed herein provide an ESD circuit, including a protection component and a thermal shutoff component, for protecting a circuit from an ESD event. In various examples disclosed herein, the thermal shutoff component protects the ESD circuit from damage caused by high temperatures by modifying an electrical characteristic (e.g., a gate voltage) of the protection component in response to an increase in temperature. In various examples disclosed herein, the thermal shutoff component reduces current leak caused by higher operating temperatures of the ESD circuit by modifying an electrical characteristic (e.g., a gate voltage) of the protection component in response to an increase in temperature.

Finally, it should be understood that any of the above-described concepts can be used alone or in combination with any or all of the other above-described concepts. Although various examples have been disclosed and described, it is understood, recognized, and/or contemplated that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. A device comprising:
a first power rail;
a second power rail;
an electrical protection component conductively coupled between the first and second power rails, the electrical protection component configured to monitor a voltage characteristic of the first power rail to thereby detect an electrical event; and
a thermal protection component conductively coupled between the power rails, and to the electrical protection component, the thermal protection component including a temperature-sensitive transistor configured to alter an electrical characteristic of the electrical protection component in response to a change in temperature of the device.

2. The device of claim 1, wherein temperature-sensitive component is a bipolar junction transistor (BJT).

3. The device of claim 1, wherein the electrical characteristic is a failure voltage of the electrical protection component.

4. The device of claim 1, wherein the electrical characteristic is a bias voltage at a control terminal of the electrical protection component.

5. The device of claim 2, wherein the BJT includes:
a base conductively coupled to the first power rail;
a collector conductively coupled to a control terminal of the electrical protection component; and
an emitter conductively coupled to the second power rail.

6. The device of claim 5, wherein the thermal protection component further includes:
a first transistor having a first gate terminal, a first source/drain terminal, and a second source/drain terminal, the second source/drain terminal conductively coupled to the base of the BJT;
a first resistor conductively coupled between the first power rail and the first source/drain terminal of the first transistor;
a second resistor conductively coupled between the first gate terminal of the first transistor and the second power rail; and
a third resistor conductively coupled between a node connecting the base of the BJT and the second source/drain terminal of the first transistor, and the second power rail.

7. The device of claim 6, wherein the first transistor is a laterally-diffused metal-oxide semiconductor (LDMOS) field-effect-transistor.

8. The device of claim 5, wherein the electrical protection component includes:
a first transistor having a first gate terminal; and
a second transistor having a second gate terminal, wherein the collector of the BJT is electrically coupled to the first gate terminal of the first transistor to modulate a voltage at the second gate terminal in response to the change in temperature of the device.

9. The device of claim 5, wherein the electrical protection component includes:
a first transistor having a first gate terminal; and
a second transistor having a second gate terminal, wherein the collector of the BJT is conductively coupled to the second gate terminal of the second transistor to alter a bias voltage of the second transistor in response to the change in temperature of the device.

10. The device of claim 1, wherein the monitored voltage characteristic of the first power rail is a transient change of voltage between the first power rail and the second power rail, and
wherein the electrical protection component is configured to discharge a current associated with the transient change of voltage to the second power rail on the condition that a characteristic of the transient change of voltage differs from a predetermined value by a predetermined difference value.

11. A device comprising:
a power rail;
a reference rail;
an electrostatic discharge (ESD) protection component conductively coupled to the power rail and the reference rail; and
a thermal protection component including:
a first transistor including a first gate terminal conductively coupled to the reference rail; and
a bipolar junction transistor (BJT) including:
a base conductively coupled to the first transistor;
a collector configured to provide a control signal to a control terminal of the ESD protection component; and
an emitter conductively coupled to the reference rail, wherein the BJT is configured to alter the control signal in response to a change of temperature of the device.

12. The device of claim 11, wherein the ESD protection component includes a second transistor having a second gate terminal, and wherein the collector is conductively coupled to the second gate terminal to alter a failure voltage of the ESD protection component in response to the change in temperature of the device.

13. The device of claim 12, wherein the ESD protection component further includes a third transistor having a third gate terminal, wherein the third gate terminal is conductively coupled to the second transistor, and wherein the failure voltage of the ESD protection component is a failure voltage of the third transistor .

14. The device of claim 11, wherein the ESD protection component includes a second transistor having a second gate terminal, wherein the collector is conductively coupled to the second gate terminal to alter a bias voltage of the second transistor in response to an increase in temperature of the device.

15. The device of claim 14, wherein the ESD protection component further includes a third transistor that is conductively coupled to the second gate terminal of the second transistor, wherein the third transistor is configured to activate the second transistor in response to an ESD event on the power rail or the reference rail, and wherein the third transistor has a different threshold voltage than the second transistor.

16. The device of claim 11, wherein the thermal protection component further includes:
a first resistor conductively coupled between the power rail and the first transistor;
a second resistor conductively coupled between the reference rail and the first transistor; and
a third resistor conductively coupled between the first transistor, the base of the BJT, and the reference rail.

17. A method of manufacturing an integrated circuit, comprising:
forming an electrostatic discharge (ESD) protection circuit on or over a substrate, the ESD protection circuit configured to operate responsive to a transient electrical event on a power rail; and
forming a thermal protection circuit on or over the substrate, the thermal protection circuit being connected to a control terminal of the ESD protection circuit, wherein the thermal protection circuit includes a temperature sensitive component configured to modulate a control voltage at the control terminal in response to a change of temperature of the integrated circuit.

18. The method of claim 17, further comprising:
wherein the forming of the thermal protection circuit on the substrate includes:
forming a first transistor conductively coupled between the power rail and a ground rail; and
forming a bipolar junction transistor (BJT) conductively coupled between the first transistor and the ESD protection circuit.

19. The method of claim 18, wherein the forming of the ESD protection circuit on the substrate includes forming a second transistor conductively coupled between the power rail and the ground rail, and to a collector of the BJT.

20. The method of claim 17, wherein the forming of the temperature sensitive component includes forming a transistor selected from the group consisting of a bipolar junction transistor (BJT) and an insulated-gate bipolar transistor (IGBT).
